(19) United States
(12) Patent Application Publication
(10) Pub. No.: US 2025/0359090 A1
(43) Pub. Date: Nov. 20, 2025

(54) DEVICE HAVING MULTIPHASE DIELECTRIC LAYER AND METHOD

(71) Applicant: Taiwan Semiconductor Manufacturing Co., Ltd., Hsinchu (TW)

(72) Inventors: You Sheng LIU, Hsinchu (TW); Yu-Kai CHANG, Hsinchu (TW); Pei-Chun LIAO, Hsinchu (TW); Yu-An HUANG, Hsinchu (TW)

(73) Assignee: Taiwan Semiconductor Manufacturing Co., Ltd., Hsinchu (TW)

(21) Appl. No.: 19/284,422

(22) Filed: Jul. 29, 2025

Related U.S. Application Data
(63) Continuation of application No. 18/352,055, filed on Jul. 13, 2023.
(60) Provisional application No. 63/491,894, filed on Mar. 23, 2023.

(51) Int. Cl. H10D 1/68

(52) U.S. Cl. CPC H10D 1/692

(57) ABSTRACT

A device includes: a first electrode; a first interfacial layer in contact with the first electrode; a first insertion layer on the first interfacial layer, the first insertion layer having first orthorhombic-phase (O-phase) regions or first monoclinic-phase (M-phase) regions in a first area ratio that exceeds about 70%; a first dielectric layer on the first insertion layer, the first dielectric layer having tetragonal-phase (T-phase) regions in a second area ratio that exceeds those of second O-phase regions and second M-phase regions; a second insertion layer on the first dielectric layer, the second insertion layer having third O-phase regions or third M-phase regions in a third area ratio that exceeds about 70%; a second interfacial layer in contact with the second insertion layer, the second interfacial layer being a different material than the first interfacial layer; and a second electrode on the second interfacial layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic cross-sectional side views of a portion of an IC device in accordance with embodiments of the present disclosure.

FIGS. 2A-8C are diagrammatic cross-sectional side views of a portion of an IC device in accordance with embodiments of the present disclosure.

FIGS. 9A-10F are views of various embodiments of an IC device at various stages of fabrication according to various aspects of the present disclosure.

FIGS. 11 and 12 are flowcharts illustrating methods of fabricating a semiconductor device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to electronic devices, and more particularly to electronic devices that include integrated capacitors having hybrid phase dielectric layers. As on-chip power density increases in advanced nodes, reducing voltage drop during load switching in on-chip power delivery networks becomes increasingly difficult. High capacitance (C) density metal-insulator-metal (MIM) capacitor structures may improve voltage drop while maintaining area efficiency. To achieve high C density and low leakage, polycrystalline tetragonal (T phase), orthorhombic (O phase) and monoclinic (M phase) Zr-doped HfO2 (HZO) films with high dielectric constant and high bandgap are included in the MIM capacitor structures.

In some MIM structures, standalone T-phase HZO layer(s) having dielectric constant er of about 35 have been adopted to achieve high C density (e.g., about 30 to 50 fF/μm²). However, MIM structures that only include T-phase HZO layer(s) have insufficient time-dependent dielectric breakdown (TDDB), making it difficult to maintain reliability (e.g., mean time to failure, or “MTTF”) beyond 10 years.

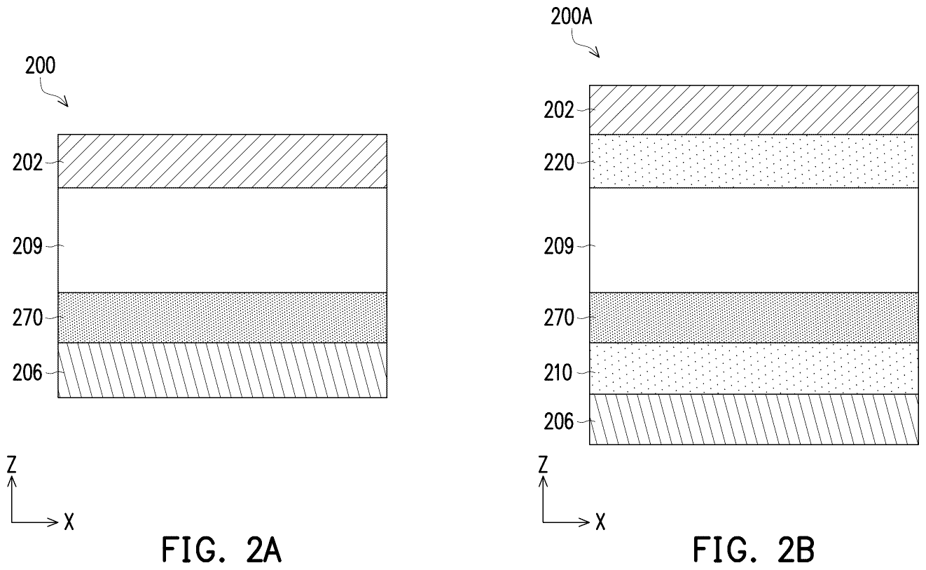

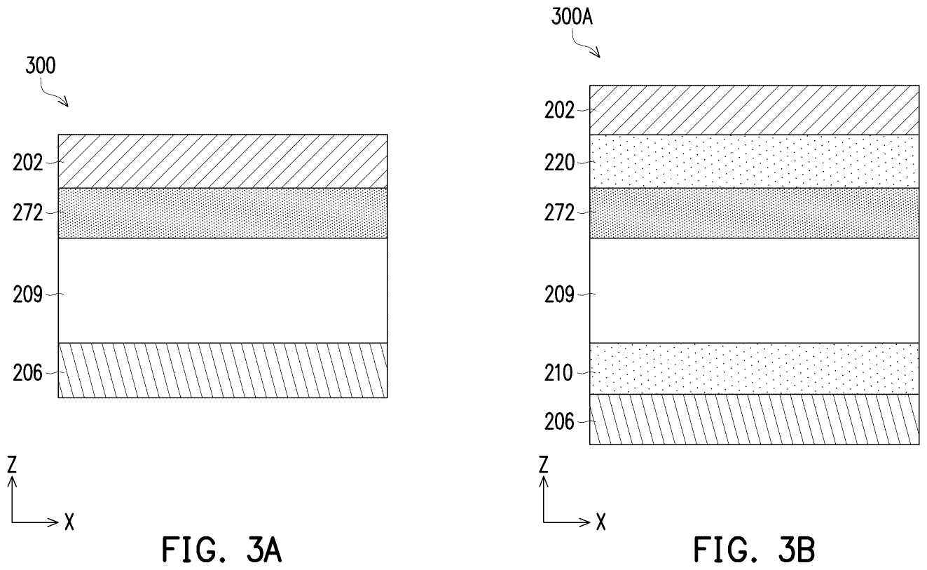

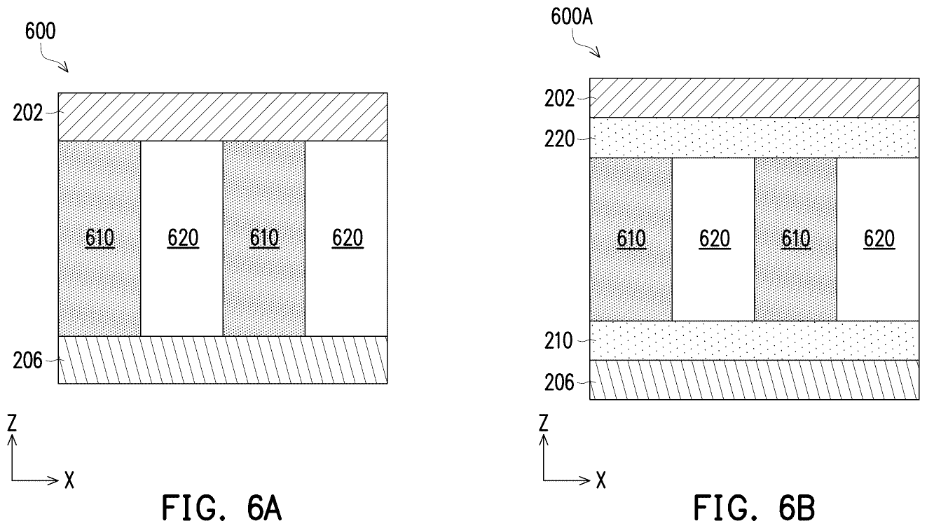

In embodiments of the disclosure, an MIM structure includes insertion layers. The MIM structures of the embodiments have improved long-term reliability while maintaining beneficial capacitance density. Insertion layers with orthorhombic or monoclinic phase (e.g., O or M phase from additional high-k layer) are disposed in the MIM structure to improve MTTF without capacitance degradation penalty. The high-k MIM capacitors include a conductive material (CM) as a top electrode, a top interfacial layer (IL), a bottom IL, a first high-k layer between ILs and CM as a bottom electrode. In embodiments of the disclosure, novel insertion layers are included in high-k MIM capacitors. A first O or M phase (from second high-k layer) insertion layer may be between the first high-k layer and the top IL as a top insertion layer. The top insertion layer is used as a trap-assisted tunneling (TAT) blocking layer due to low defective phases. A second O or M phase (from third high-k layer) insertion layer may be between the first high-k layer and the bottom IL as a bottom insertion layer. The O or M phase insertion layers may be present on only one side of the first high-k layer, which is described in greater detail with reference to FIGS. 2A-3B below. Some embodiments include O or M phase pillars, which are described in greater detail with reference to FIGS. 6A-8C below.

With the same thickness of IL and high-k dielectric layer(s), the mixture of O and T phases (or M and T phases) can improve MTTF without C degradation. Traps are difficult to be generated in O or M phase nanolaminated layers, which blocks or reduces the trap-assisted tunneling (TAT) flow between the IL and T phase layer, which is beneficial to MTTF.

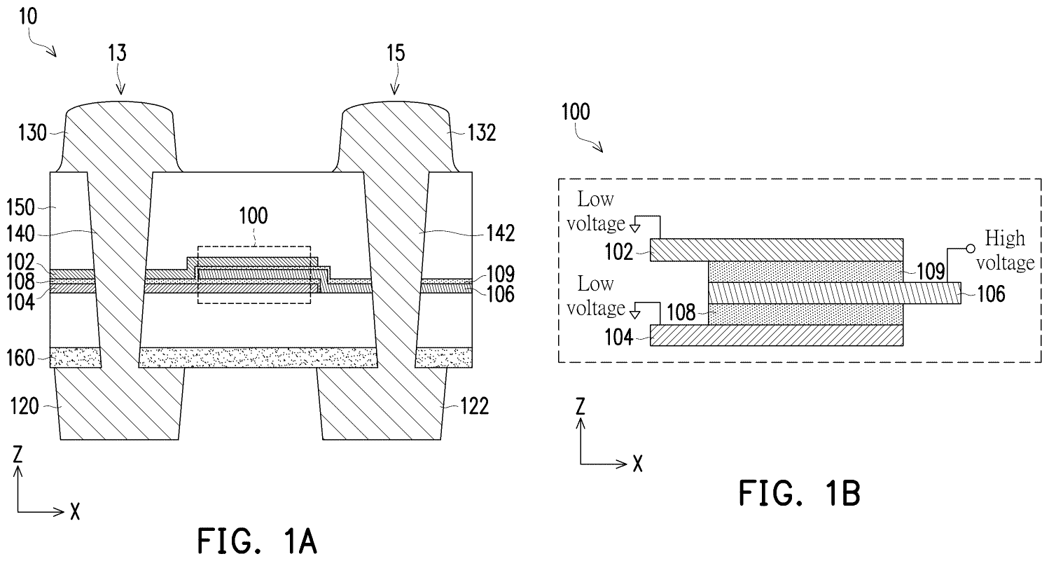

FIGS. 1A and 1B are diagrammatic cross-sectional side views of a portion of an IC chip 10 in accordance with various embodiments. FIG. 1A depicts a portion of the IC chip 10 including an integrated capacitor 100. FIG. 1B depicts the integrated capacitor 100 in greater detail in accordance with various embodiments.

In FIG. 1A, a portion of the IC chip 10 is shown. The IC chip 10 includes an integrated capacitor 100. The integrated capacitor 100 is coupled to a first metal feature 13 and a second metal feature 15. The integrated capacitor 100 may be positioned in a first dielectric 150 that is on a top metal (TM) conductive layer of the IC chip 10. A second dielectric 160 may be between the first dielectric 150 and the TM conductive layer. The top metal conductive layer may be an uppermost metal layer of a back-end-of-line (BEOL) interconnect structure that is on a device layer of the IC chip 10. The device layer may refer to a multilayer structure that includes transistors, such as nanostructure transistors. The nanostructure transistors may include field effect transistors (FETs), such as fin-type FETs (FinFETs), nanosheet FETs (NSFETs), nanowire FETs (NWFETs), gate-all-around FETs (GAAFETs), combinations thereof and the like. A front-end-of-line (FEOL) interconnect structure may include contacts and/or vias that are in direct contact with source, drain and gate structures of the FETs. The BEOL interconnect structure may connect directly to the FEOL interconnect structure or may be connected thereto indirectly via a mid-end-of-line (MEOL) interconnect structure. In some embodiments, the integrated capacitor 100 is positioned in the MEOL interconnect structure, the BEOL interconnect structure or both.

The first and second metal features 13, 15 may each include a top metal feature 120, 122, a conductive via 140, 142 and an RDL metal feature 130, 132, respectively. The top metal features 120, 122 may be or include a conductive material, which may be a metal or alloy including Cu, W or another suitable conductive material. The conductive vias 140, 142 may be the same material as the top metal features 120, 122. The RDL metal features 130, 132 may be the same or different material as the top metal features 120, 122 and the conductive vias 140, 142.

In FIG. 1B, the integrated capacitor 100 may be a MIM capacitor. In some embodiments, the integrated capacitor 100 includes a bottom electrode 104, a top electrode 102 and a middle electrode 106 between the top and bottom electrodes 102, 104. A first dielectric layer 108 is between the bottom electrode 104 and the middle electrode 106. A second dielectric layer 109 is between the top electrode 102 and the middle electrode 106.

The top, bottom and middle electrodes 102, 104, 106 may be or include conductive material(s), which may be a metal, alloy or conductive ceramic, such as TiN, W or other suitable conductive material. The first and second dielectric layers 108, 109 may be thin-film layers that include high-k dielectrics, such as zirconium-doped hafnium oxide (HZO) or the like. The first and second dielectric layers 108, 109 may include T-phase HZO and one or more insertion layers that include O-phase and/or M-phase HZO, as will be described in greater detail with reference to FIGS. 2A-8C below.

As shown in FIG. 1B, the top electrode 102 and the bottom electrode 104 may be coupled to a low voltage or ground and the middle electrode 106 may be coupled to a high voltage or signal voltage. In some embodiments, the middle electrode 106 may be coupled to the low voltage or ground and the top electrode 102 and the bottom electrode 104 may be coupled to the high voltage or signal voltage.

The first dielectric 150 may be an RDL dielectric, which may be a polymer, an oxide of silicon, or the like. The second dielectric 160 may be an etch stop layer, and may include a different material than the first dielectric 150, which may have different etch selectivity than the first dielectric 150. In some embodiments, the first dielectric 150 is an interlayer dielectric (ILD), for example, of the BEOL interconnect structure, and may be or include silicon dioxide, carbon doped silicon dioxide, silicon oxynitride, borosilicate glass (BSG), phosphoric silicate glass (PSG), borophosphosilicate glass (BPSG), fluorinated silicate glass (FSG), a porous dielectric material, or the like. The second dielectric 160 may be an etch stop layer formed of silicon nitride, silicon carbo-nitride, or the like.

FIGS. 2A and 2B are diagrammatic cross-sectional views of integrated capacitors 200, 200A in accordance with various embodiments. The integrated capacitors 200, 200A may be embodiments of the integrated capacitor 100 of FIGS. 1A and 1B, and many features thereof may be the same as or similar to those of the integrated capacitor 100. For example, materials of electrodes 202, 206 of the integrated capacitors 200, 200A may be the same as or similar to those of electrodes 102, 104, 106 of the integrated capacitor 100.

In FIG. 2A, the integrated capacitor 200 includes a first electrode 206, a second electrode 202, a first dielectric layer 209 and an O- or M-phase first insertion layer 270. In some embodiments, the first electrode 206 is a middle electrode, such as the middle electrode 106, and the second electrode 202 is a top electrode, such as the top electrode 102. In some embodiments, the first electrode 206 is a bottom electrode, such as the bottom electrode 104, and the second electrode is a middle electrode, such as the middle electrode 106. In some embodiments, the integrated capacitor 200 only includes two electrodes, such that the first electrode 206 is a bottom electrode and the second electrode 202 is a top electrode. It should be understood that the top electrode refers to an electrode that is distal a device layer of an integrated chip and that the bottom electrode refers to an electrode that is proximal the device layer of the integrated chip. For example, the bottom electrode may be between the top electrode and a BEOL interconnect structure, a MEOL interconnect structure, FEOL features, transistors (e.g., GAAFETs) or the like.

The first dielectric layer 209 may be similar in many respects to the first and/or second dielectric layers 108, 109. The first dielectric layer 209 may be or include HZO, and may have thickness that is less than about 5 nanometers (nm). In some embodiments, the first dielectric layer 209 is T-phase HZO. It should be understood that “T-phase” includes the meaning that area ratio of T-phase HZO in the layer is greater than either of O-phase and M-phase HZO in the layer. For example, the first dielectric layer 209 that is “T-phase” may include about 5% M-phase HZO, about 39% O-phase HZO and about 56% T-phase HZO. In some embodiments, the first dielectric layer 209 has an area ratio of T-phase HZO that is greater than about 50%, 55%, 60% or another suitable percentage. In some embodiments, in a T-phase HZO layer, each of the area ratio of O-phase HZO and M-phase HZO is less than about 70%.

The first insertion layer 270 may be an O-phase HZO layer or an M-phase HZO layer, has thickness less than about 5 nm and has different area ratio of T-phase HZO than the first dielectric layer 209. A higher electric field in high-k dielectric layers is beneficial for reducing traps generated in an HZO layer over a long period of voltage biasing. An O-phase HZO layer has higher electric field, which is beneficial for reducing trap generation. As such, the first insertion layer 270 may be operable to reduce trap generation, which blocks or reduces TAT flow in the first dielectric layer 209, which is beneficial to increasing TDDB and MTTF. An M-phase HZO layer has similarly beneficial properties as the O-phase HZO layer, and may reduce trap generation, which is beneficial to increase TDDB and MTTF. It should be understood that “O-phase” includes the meaning of an HZO layer in which an area ratio of O-phase HZO exceeds about 70%, 60%, 50% or another suitable percentage. For example, an O-phase HZO layer may include about 69% O-phase HZO, about 3% M-phase HZO and about 28% T-phase HZO. It should be understood that “M-phase” includes the meaning of an HZO layer in which an area ratio of M-phase HZO is greater than about 10%, 15%, 20% or another suitable percentage. Generally, M-phase HZO may be present in lower area ratios than O-phase HZO and T-phase HZO and the first insertion layer 270 may still be an “M-phase HZO layer.” For example, an M-phase HZO layer may include about 13% M-phase HZO, about 47% O-phase HZO and about 40% T-phase HZO. In some embodiments, the M-phase HZO layer includes M-phase HZO at an area ratio that exceeds about 70%.

In FIG. 2B, the integrated capacitor 200A is similar in most respects to the integrated capacitor 200. In the integrated capacitor 200A, a first IL 210 is between the first insertion layer 270 and the first electrode 206 and a second IL 220 is between the first dielectric layer 209 and the second electrode 202. The first IL 210 may be a thin layer that includes an oxide of material of the first electrode 206. For example, the first IL 210 may include tungsten oxide, titanium oxynitride, or the like. The first insertion layer 270 and the first electrode 206 may be in direct contact with the first IL 210. The second IL 220 may be an oxide of the first dielectric layer 209, such as HZO including higher oxygen percentage than that of the first dielectric layer 209. In some embodiments, the first IL 210 is a different material than the second IL 220. In some embodiments, one or both of the first and second ILs 210, 220 is a dielectric layer that is not an oxide of material of the respective underlying layer. For example, the first or second IL 210, 220 may be a dielectric material that is or includes SiO₂, SiN, SiCN, SiC, SiOC, SiOCN, HfO₂, ZrO₂, ZrAlOₓ, HfAlOₓ, HfSiOₓ, Al₂O₃, BN, or other suitable dielectric material.

FIGS. 3A and 3B are diagrammatic cross-sectional views of integrated capacitors 300, 300A in accordance with various embodiments. The integrated capacitors 300, 300A may be embodiments of the integrated capacitor 100 of FIGS. 1A and 1B, and many features thereof may be the same as or similar to those of the integrated capacitor 100. The integrated capacitors 300, 300A may be similar in many respects to the integrated capacitors 200, 200A of FIGS. 2A and 2B, and many features thereof may be the same as or similar to those of the integrated capacitors 200, 200A.

In FIG. 3A, the integrated capacitor 300 includes a second insertion layer 272 that is positioned between the first dielectric layer 209 and the second electrode 202 and has thickness less than about 5 nm. The second insertion layer 272 may be in direct contact with the first dielectric layer 209 and the second electrode 202. In some embodiments, the second insertion layer 272 is separated from the second electrode 202 by the second IL 220, as depicted in FIG. 3B. The second insertion layer 270 is similar in many respects to the first insertion layer 272. In some embodiments, the second insertion layer 272 is an O-phase HZO layer or an M-phase HZO layer. In FIG. 3B, the second IL 220 may be an oxide of the second insertion layer 272 or a dielectric layer including one or more of the materials described with reference to FIG. 2B.

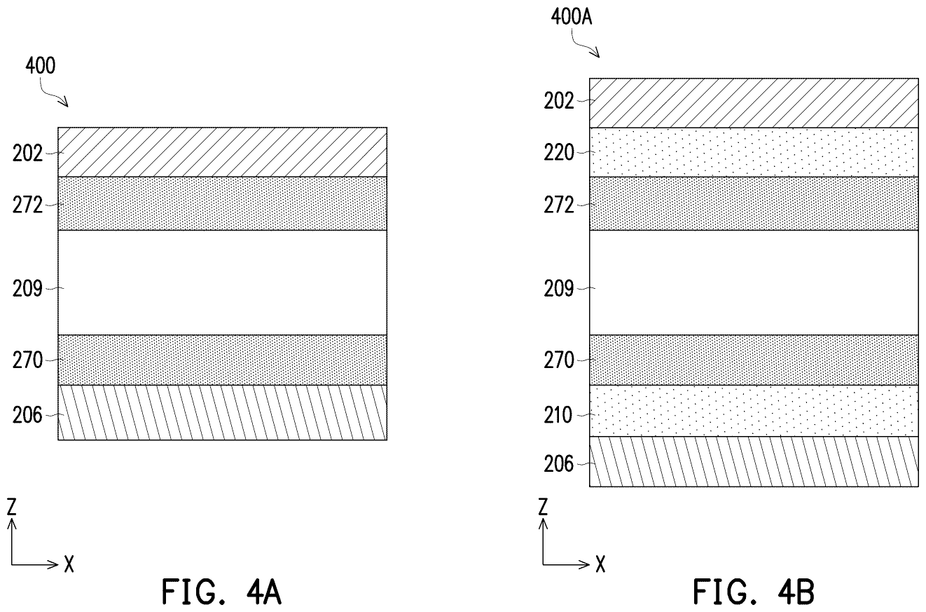

FIGS. 4A and 4B are diagrammatic cross-sectional views of integrated capacitors 400, 400A in accordance with various embodiments. The integrated capacitors 400, 400A may be embodiments of the integrated capacitor 100 of FIGS. 1A and 1B, and many features thereof may be the same as or similar to those of the integrated capacitor 100. The integrated capacitors 400, 400A may be similar in many respects to the integrated capacitors 200, 200A, 300, 300A of FIGS. 2A-3B, and many features thereof may be the same as or similar to those of the integrated capacitors 200, 200A, 300, 300A. In FIGS. 4A and 4B, the integrated capacitors 400, 400A include both the first and second insertion layers 270, 272. Inclusion of the first and second insertion layers 270, 272 may increase MTTF by five times or more over structures that do not include the O- or M-phase insertion layers 270, 272.

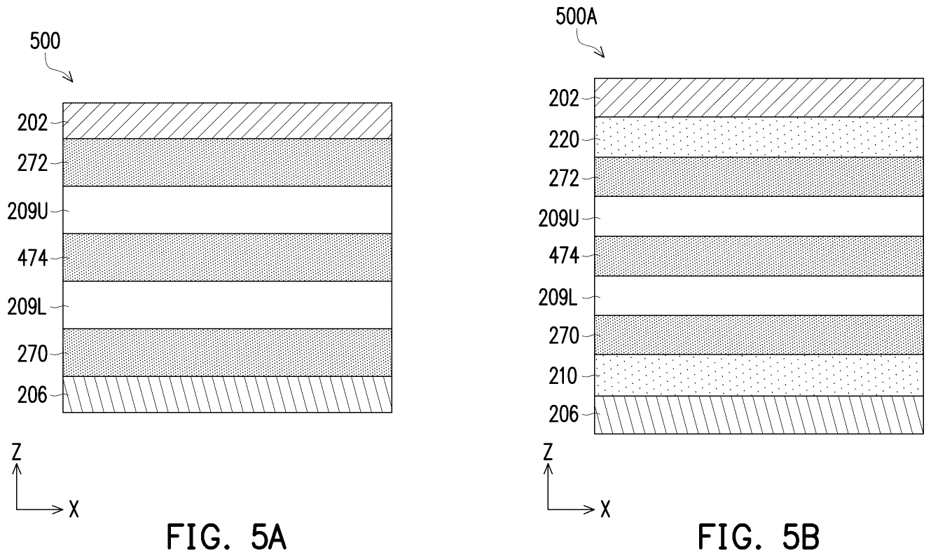

FIGS. 5A and 5B are diagrammatic cross-sectional views of integrated capacitors 500, 500A in accordance with various embodiments. The integrated capacitors 500, 500A may be embodiments of the integrated capacitor 100 of FIGS. 1A and 1B, and many features thereof may be the same as or similar to those of the integrated capacitor 100. The integrated capacitors 500, 500A may be similar in many respects to the integrated capacitors 200, 200A, 300, 300A of FIGS. 2A-3B, and many features thereof may be the same as or similar to those of the integrated capacitors 200, 200A, 300, 300A. In FIGS. 5A and 5B, the integrated capacitors 500, 500A include both the first and second insertion layers 270, 272 and also include a third insertion layer 474. In some embodiments, as depicted in FIGS. 5A and 5B, the first dielectric layer 209 may include an upper dielectric layer 209U and a lower dielectric layer 209L that are separated by the third insertion layer 474. The upper and lower dielectric layers 209U, 209L may be thinner than the first dielectric layer 209 and may include the same or similar materials as described for the first dielectric layer 209. The third insertion layer 474 may be an O-phase HZO layer or an M-phase HZO layer and may be similar in most respects to the first and second insertion layers 270, 272.

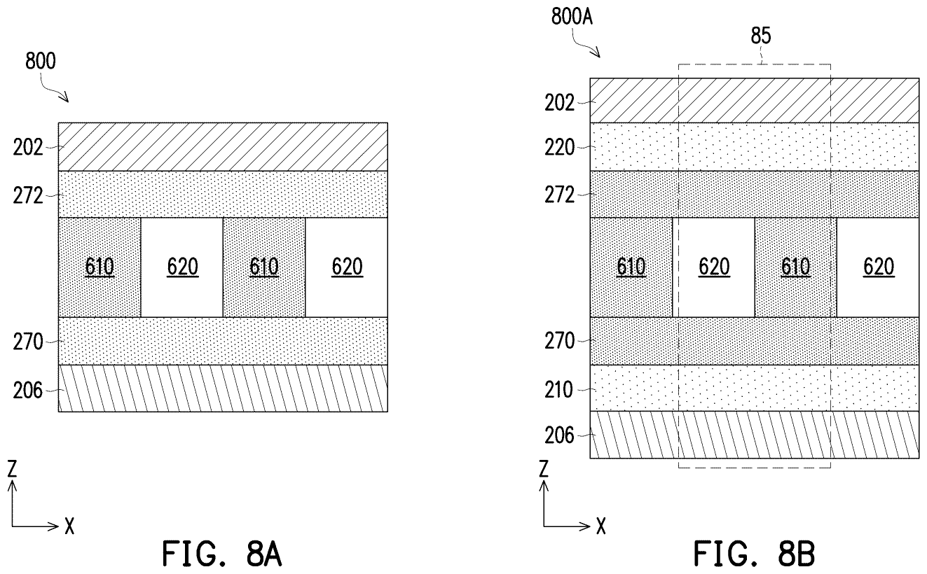

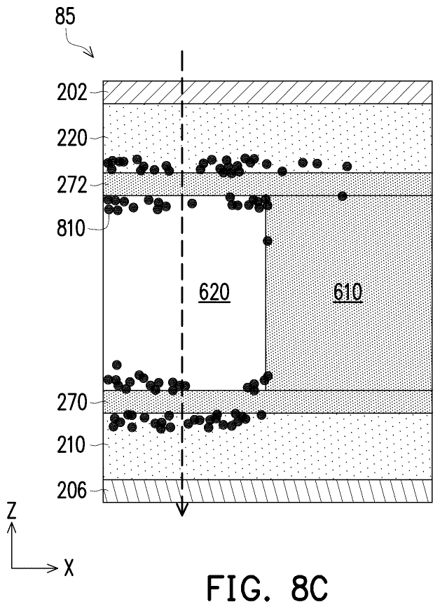

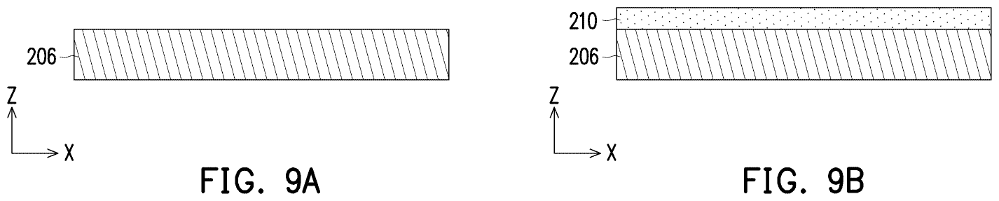

FIGS. 6A-8C depict integrated capacitors 600, 600A, 700, 700A, 800, 800A that include insertion pillars 610, 620 and optionally include the first and/or second insertion layers 270, 272. While not specifically depicted in the Figures, it should be understood that the third insertion layer 474 may be included in the integrated capacitors 800, 800A of FIGS. 8A-8C. For example, two layers of insertion pillars 610, 620 may be stacked vertically and separated from each other with the third insertion layer 474 therebetween.

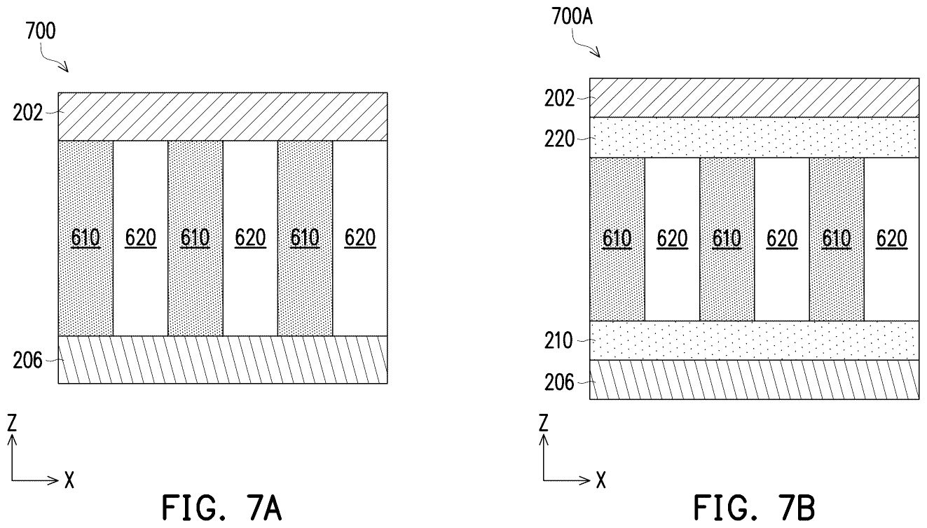

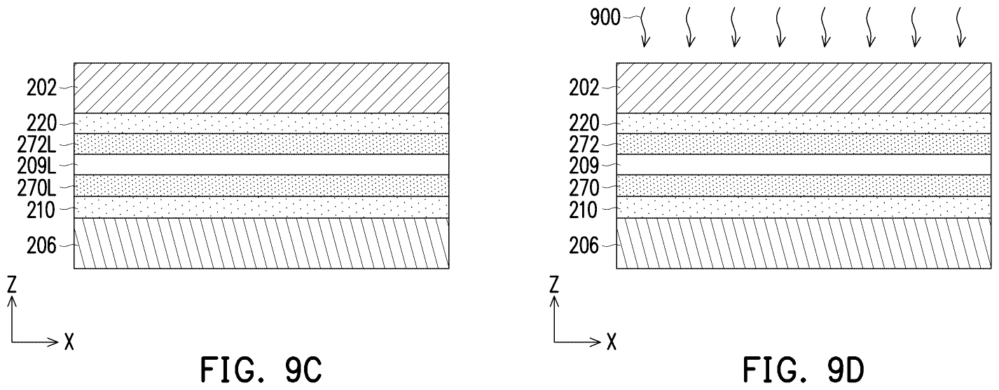

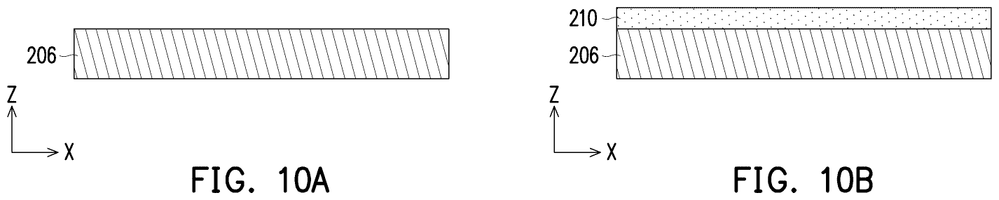

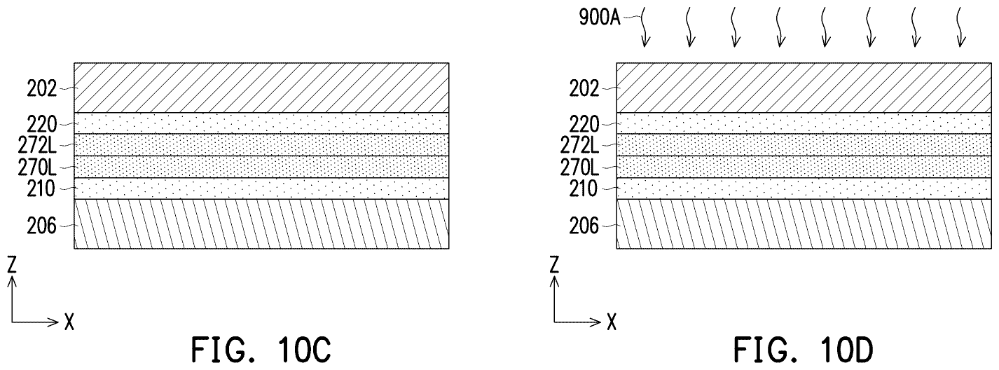

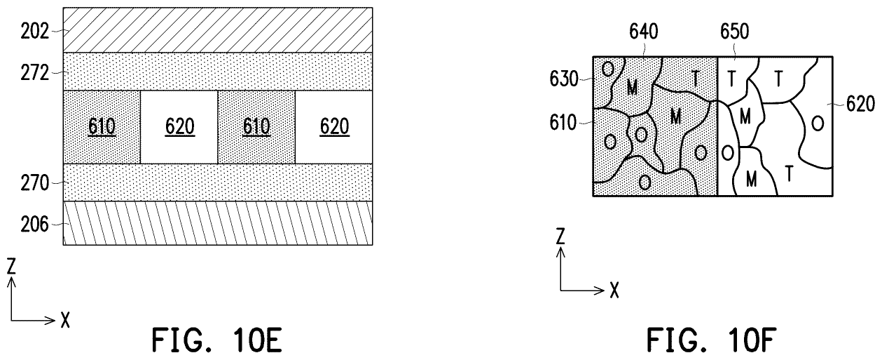

In FIGS. 6A and 6B, integrated capacitors 600, 600A are depicted that include two O-phase insertion pillars 610 and two T-phase insertion pillars 620 that are arranged in alternating sequence from left to right along the horizontal direction (e.g., X-axis direction in FIGS. 6A and 6B). In some embodiments, as depicted in FIGS. 7A and 7B, integrated capacitors 700, 700A may include more than two (e.g., three) each of the O-phase and T-phase insertion pillars 610, 620. In some embodiments, fewer than two of one or both of the O-phase and T-phase insertion pillars 610, 620 are included. In some embodiments, one or more of the O-phase insertion pillars 610 is replaced with an M-phase insertion pillar 610. The insertion pillars 610, 620 may have height in the Z-axis direction in a range from about 4 nm to about 20 nm. In FIG. 6B, the first IL 210 is in direct contact with the bottom surfaces of the O-phase and T-phase insertion pillars 610, 620 and the second IL 220 is in direct contact with the upper surfaces of the O-phase and T-phase insertion pillars 610. In some embodiments, although the second IL 220 overlaps the O-phase and T-phase insertion pillars 610, 620, the second IL 220 may be a continuous layer that has substantially uniform material composition over the respective insertion pillars 610, 620. For example, although regions of the second IL 220 overlap the O- or M-phase insertion pillars 610 that have zirconium content that exceeds that of the T-phase insertion pillars 620, zirconium content of the second IL 220 may be substantially the same along the entirety of the second IL 220 along the X-axis direction. This is because the second IL 220 is formed prior to an annealing operation that forms the insertion pillars 610, 620. Detailed description of the annealing operation is provided with reference to FIGS. 9D and 10D below.

In FIGS. 8A and 8B, integrated capacitors 800, 800A include insertion pillars 610, 620 and insertion layers 270, 272. The insertion layers 270, 272 may be between the insertion pillars 610, 620 and the first electrode 206 and the between the insertion pillars 610, 620 and the second electrode 202, respectively. In some embodiments, the insertion layer 270 or the insertion layer 272 is omitted.

In FIGS. 6A-8B, the insertion pillars 610, 620 are depicted as having vertical sidewalls that are straight. In some embodiments, the interface between different phases of HZO is not a regular straight line. In some embodiments, a gradient exists between different phases of HZO, such as between the O-phase insertion pillar 610 and the T-phase insertion pillar 620. An embodiment of the interface between insertion pillars 610, 620 is described with reference to FIG. 10F.

FIG. 8C depicts a region 85 of the integrated capacitor 800A of FIG. 8B. In FIG. 8C, TAT flow is depicted by a dashed arrow in the vertical direction (e.g., the Z-axis direction). Traps 810 are present in the first and second ILs 210, 220 and the T-phase insertion pillar 620 and to a much lesser extent are present in the O-phase (or M-phase) insertion pillar 610. Fewer traps 810 are generated in the O-phase insertion pillar 610 and the O-phase insertion layers 270, 272, which blocks or reduces the trap-assisted tunneling (TAT) flow between the first and second ILs 210, 220 and the T-phase insertion pillar 620. Inclusion of the O-phase insertion layers 270, 272 and the O-phase insertion pillars 610 is beneficial to MTTF, and may increase MTTF by about seven times relative to integrated capacitor structures that do not include the insertion layers 270, 272 or the insertion pillars 610, 620.

Integrated capacitors having various MIM structures with different phases (M, O and T) of HZO have been described with reference to FIGS. 2A-8C. The various insertion layers 270, 272, 474, 610, 620 may include HZO that is deposited in different forms (e.g., nanolaminated and/or pillar). In some embodiments, deposition order and/or arrangement of the insertion layers 270, 272, 474, 610, 620 may include any combination of O- and T-phase layers and/or M- and T-phase layers. For example, the first and second insertion layers 270, 272 in FIGS. 5A and 5B may be O-phase layers and the third insertion layer 474 may be an M-phase layer. In some embodiments, one or more T-phase layers is in direct contact with one or more of the first and second ILs 210, 220. For example, the first insertion layer 270 in FIG. 5B may be omitted, such that the lower first dielectric layer 209L is in direct contact with the first IL 210. In some embodiments, one or more of the insertion layers 270, 272, 474 may include another doped hafnium oxide material, such as HfₓSi₁₋ₓO₂ (HSO) instead of HfₓZr₁₋ₓO (HZO). In some embodiments, O-phase insertion layers, such as the insertion layers 270, 272, 474 may be included in ZrO₂-based capacitance structures, such as ZAZ capacitance structures that include a stack of ZrO₂, Al₂O₃ and ZrO₂ layers.

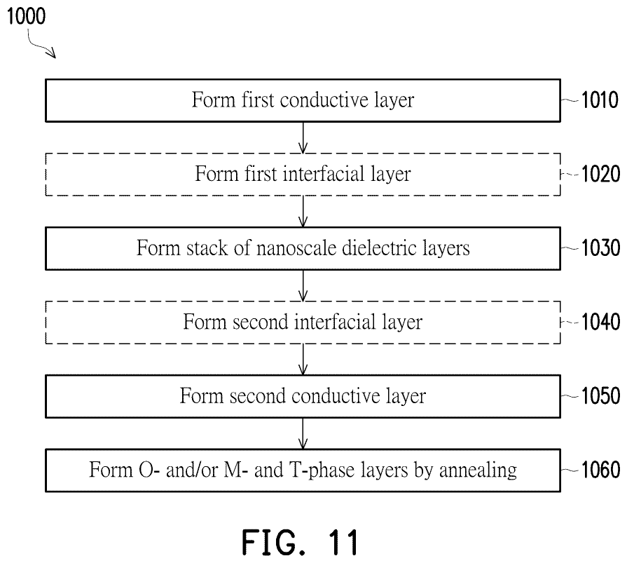

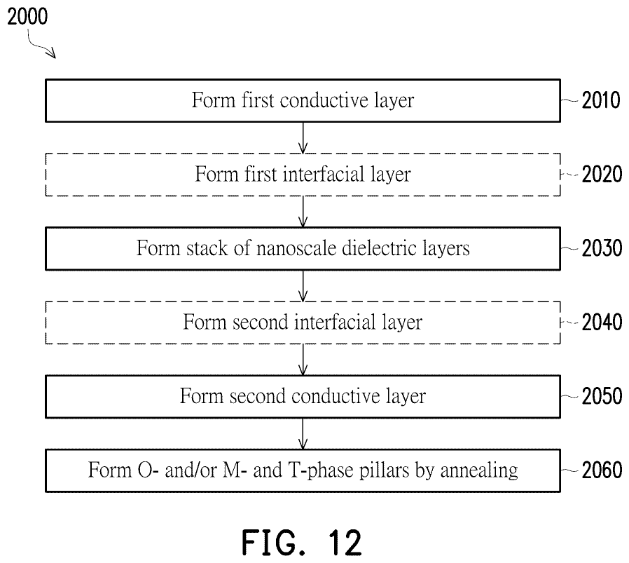

FIGS. 9A-9D and 10A-10F are views of various embodiments of an IC device, e.g., the IC chip 10, at various stages of fabrication according to various aspects of the present disclosure. FIG. 11 is a flowchart illustrating a method 1000 of fabricating a semiconductor device according to various aspects of the present disclosure. FIG. 12 is another flowchart illustrating a method 2000 of fabricating a semiconductor device according to various aspects of the present disclosure. The various stages of fabrication of the IC device illustrated in FIGS. 9A-9D may be performed in accordance with the method of FIG. 11. The various stages of fabrication of the IC device illustrated in FIGS. 10A-10F may be performed in accordance with the method of FIG. 12. FIGS. 11 and 12 illustrate flowcharts of methods 1000, 2000 for forming an IC device or a portion thereof from a workpiece, according to one or more aspects of the present disclosure. Methods 1000, 2000 are examples and are not intended to limit the present disclosure to what is explicitly illustrated in methods 1000, 2000. Additional acts can be provided before, during and after the methods 1000, 2000 and some acts described can be replaced, eliminated, or moved around for additional embodiments of the methods. For example, formation of interfacial layers in acts 1020, 1040, 2020 and 2040 may be omitted. Not all acts are described herein in detail for reasons of simplicity. Methods 1000, 2000 are described below in conjunction with fragmentary perspective and/or cross-sectional views of a workpiece, shown in FIGS. 9A-9D and 10A-10F, at different stages of fabrication according to embodiments of methods 1000, 2000. For avoidance of doubt, throughout the figures, the X direction is perpendicular to the Z direction. It is noted that, because the workpiece may be fabricated into a semiconductor device, the workpiece may be referred to as the semiconductor device as is beneficial to the context. The methods 1000, 2000 are described with reference to elements of FIGS. 2A-8C for ease of illustration but may also form structures different than those depicted in and described with reference to FIGS. 2A-8C.

In FIG. 9A, a first electrode 206 is formed, corresponding to act 1010 of method 1000. The first electrode 206 may be formed in a dielectric layer, such as an RDL dielectric layer, an ILD layer or the like, and may be or include tungsten, titanium nitride, or another suitable conductive material. The first electrode 206 may be formed by a suitable deposition operation, such as a PVD, CVD, ALD or the like.

In FIG. 9B, following formation of the first electrode 206, a first IL 210 is formed on the first electrode 206, corresponding to act 1020 of method 1000. In some embodiments, the first IL 210 is a native oxide layer that is formed by exposing the first electrode 206 to air, water or an oxygen-containing environment. In some embodiments, the first IL 210 is a dielectric layer that is different than a native oxide layer of the first electrode 206. For example, the first IL 210 may include a dielectric material formed by a PVD, CVD or ALD, the dielectric material being one or more of SiO₂, SiN, SiCN, SiC, SiOC, SiOCN, HfO₂, ZrO₂, ZrAlOₓ, HfAlOₓ, HfSiOₓ, Al₂O₃, BN, or other suitable dielectric material. In some embodiments, prior to forming the first IL 210, a plasma treatment may be performed on the first electrode 206. In some embodiments, the first IL 210 is not formed, as indicated by a dashed box for act 1020 in FIG. 11.

In FIG. 9C, following formation of the first IL 210 or following formation of the first electrode 206, a stack of nanoscale dielectric layers including a first insertion material layer 270L, a first dielectric material layer 209L and a second insertion material layer 272L is formed on the first IL 210 or directly on the first electrode 206 with no interfacial layer therebetween, corresponding to act 1030 of method 1000. Each of the first and second insertion material layers 270L, 272L may be a nanoscale dielectric layer formed by ALD that includes HZO, which may be expressed as HfₓZr₁₋ₓO₂ or HₓZ₁₋ₓO₂ (“H” represents hafnium and “Z” represents zirconium), where X is a number between 0 and 1. When X is in a range of about 0.8 to about 1, a greater proportion of HZO will form M-phase HZO after annealing. When X is in a range of about 0.4 to about 0.6, a greater proportion of HZO will form O-phase HZO after annealing. When X is in a range of about 0 to about 0.3, a greater proportion of HZO will form T-phase HZO after annealing. In some embodiments, X is in a range of about 0.4 to about 1, such that the first and second insertion material layers 270L, 272L form first and second insertion layers 270, 272, respectively that are O-phase HZO or M-phase HZO following annealing.

The first dielectric material layer 209L may be a nanoscale dielectric layer that includes HZO, which may be expressed as Hf_{y}Zr_{1-Y}O₂ or H_{Y}Z_{1-Y}O₂ (“H” represents hafnium and “Z” represents zirconium), where Y is a number between 0 and 1. In some embodiments, Y is different than X. In some embodiments, Y is less than X. In some embodiments, Y is in a range of about 0 to about 0.3, such that the first dielectric material layer 209L forms a first dielectric layer 209 that is T-phase HZO following annealing.

Following formation of the stack of nanoscale dielectric layers, an optional second IL 220 and a second electrode 202 are formed, corresponding to acts 1040 and 1050 of method 1000. The second IL 220 may be a native oxide layer that is formed by exposing the second insertion material layer 272L to air, water or an oxygen-containing environment. In some embodiments, the second IL 220 is a dielectric layer that is different than a native oxide layer of the second insertion material layer 272L. For example, the second IL 220 may include a dielectric material formed by a PVD, CVD or ALD, the dielectric material being one or more of SiO₂, SIN, SiCN, SiC, SiOC, SiOCN, HfO₂, ZrO₂, ZrAlOₓ, HfAlOₓ, HfSiOₓ, Al₂O₃, BN, or other suitable dielectric material. In some embodiments, a plasma treatment is performed on the second insertion material layer 272L prior to forming the second IL 220. In some embodiments, the second IL 220 is not formed, as indicated by a dashed box for act 1040 in FIG. 11.

Following formation of the second IL 220 or the second insertion material layer 272L, the second electrode 202 is formed. In some embodiments, prior to forming the second electrode 202, a dielectric layer is formed on the second IL 220 or the second insertion material layer 272L. The dielectric layer may be patterned to form openings by a suitable etching operation. Then, the second electrode 202 may be formed in one of the openings. The second electrode 202 may be W, TiN or another suitable conductive material that is deposited by PVD, CVD, ALD or the like.

In FIG. 9D, following formation of the stack of nanoscale dielectric layers, the optional second IL 220 and the second electrode 202, O- and/or M- and T-phase layers are formed by annealing 900 the structure of FIG. 9C, corresponding to act 1060 of method 1000. In some embodiments, a first insertion layer 270 is formed from the first insertion material layer 270L by the annealing, a second insertion layer 272 is formed from the second insertion material layer 272L by the annealing and a first dielectric layer 209 is formed from the first dielectric material layer 209L by the annealing. The first and second insertion layers 270, 272 may be O-phase and/or M-phase HZO layers. The first dielectric layer 209 may be a T-phase HZO layer. The annealing may be performed at a temperature of about 200 degrees Celsius to about 400 degrees Celsius for a duration of about several minutes to about several hours. Following the annealing, each of the O-phase HZO layer, the M-phase HZO layer and the T-phase HZO layer may include one or more regions of O-phase HZO, M-phase HZO and T-phase HZO. In the O-phase HZO layer, the content (e.g., area ratio) of O-phase HZO may be more than 70%. In the M-phase HZO layer, the content of M-phase HZO may be more than 70%. In the T-phase HZO layer, each of the content of O-phase HZO and M-phase HZO may be less than 70%.

FIGS. 10A-10F are diagrammatic cross-sectional views of a semiconductor device, such as an integrated circuit, at various phases of fabrication in accordance with various embodiments.

In FIG. 10A, a first electrode 206 is formed, corresponding to act 2010 of method 2000. The first electrode 206 may be formed in a dielectric layer, such as an RDL dielectric layer, an ILD layer or the like, and may be or include tungsten, titanium nitride, or another suitable conductive material. The first electrode 206 may be formed by a suitable deposition operation, such as a PVD, CVD, ALD or the like.

In FIG. 10B, following formation of the first electrode 206, a first IL 210 is formed on the first electrode 206, corresponding to act 2020 of method 2000. In some embodiments, the first IL 210 is a native oxide layer that is formed by exposing the first electrode 206 to air, water or an oxygen-containing environment. In some embodiments, the first IL 210 is a dielectric layer that is different than a native oxide layer of the first electrode 206. For example, the first IL 210 may include a dielectric material formed by a PVD, CVD or ALD, the dielectric material being one or more of SiO₂, SiN, SiCN, SiC, SiOC, SiOCN, HfO₂, ZrO₂, ZrAlOₓ, HfAlOₓ, HfSiOₓ, Al₂O₃, BN, or other suitable dielectric material. In some embodiments, prior to forming the first IL 210, a plasma treatment may be performed on the first electrode 206. In some embodiments, the first IL 210 is not formed, as indicated by a dashed box for act 2020 in FIG. 12.

In FIG. 10C, following formation of the first IL 210 or following formation of the first electrode 206, a stack of nanoscale dielectric layers including a first insertion material layer 270L and a second insertion material layer 272L is formed on the first IL 210 or directly on the first electrode 206 with no interfacial layer therebetween, corresponding to act 2030 of method 2000. Each of the first and second insertion material layers 270L, 272L may be a nanoscale dielectric layer formed by ALD that includes HZO, which may be expressed as HfₓZr₁₋ₓO₂ or HₓZ₁₋ₓO₂ (“H” represents hafnium and “Z” represents zirconium), where X is a number between 0 and 1. When X is in a range of about 0.8 to about 1, a greater proportion of HZO will form M-phase HZO after annealing. When X is in a range of about 0.4 to about 0.6, a greater proportion of HZO will form O-phase HZO after annealing. When X is in a range of about 0 to about 0.3, a greater proportion of HZO will form T-phase HZO after annealing. In some embodiments, X is in a range of about 0.4 to about 1, such that the first and second insertion material layers 270L, 272L form O-phase (or M-phase) and T-phase insertion pillars 610, 620 by annealing. The first dielectric material layer 209L may not be present when forming the insertion pillars 610, 620.

Following formation of the stack of nanoscale dielectric layers, an optional second IL 220 and a second electrode 202 are formed, corresponding to acts 2040 and 2050 of method 2000. The second IL 220 may be a native oxide layer that is formed by exposing the second insertion material layer 272L to air, water or an oxygen-containing environment. In some embodiments, the second IL 220 is a dielectric layer that is different than a native oxide layer of the second insertion material layer 272L. For example, the second IL 220 may include a dielectric material formed by a PVD, CVD or ALD, the dielectric material being one or more of SiO₂, SIN, SiCN, SiC, SiOC, SiOCN, HfO₂, ZrO₂, ZrAlOₓ, HfAlOₓ, HfSiOₓ, Al₂O₃, BN, or other suitable dielectric material. In some embodiments, a plasma treatment is performed on the second insertion material layer 272L prior to forming the second IL 220. In some embodiments, the second IL 220 is not formed, as indicated by a dashed box for act 2040 in FIG. 12.

Following formation of the second IL 220 or the second insertion material layer 272L, the second electrode 202 is formed. In some embodiments, prior to forming the second electrode 202, a dielectric layer is formed on the second IL 220 or the second insertion material layer 272L. The dielectric layer may be patterned to form openings by a suitable etching operation. Then, the second electrode 202 may be formed in one of the openings. The second electrode 202 may be W, TiN or another suitable conductive material that is deposited by PVD, CVD, ALD or the like.

In FIGS. 10D and 10E, following formation of the stack of nanoscale dielectric layers, the optional second IL 220 and the second electrode 202, O- and/or M- and T-phase insertion pillars are formed by annealing 900A the structure of FIG. 10C, corresponding to act 2060 of method 2000. The annealing may be performed at a temperature of about 200 degrees Celsius to about 400 degrees Celsius for a duration of about several minutes to about several hours. The resulting structure is shown in FIG. 10E. The thickness of insertion pillars 610, 620 along the Z-axis direction may be in a range from about 4 nm to about 20 nm. In some embodiments, the thickness is less than 4 nm or greater than 20 nm.

As shown in FIG. 10F, following the annealing, each of the O-phase HZO pillar 610 (or the M-phase HZO pillar 610) and the T-phase HZO pillar 620 may include one or more regions of O-phase HZO 630, M-phase HZO 640 and T-phase HZO 650. In the O-phase HZO pillar 610, the content (e.g., area ratio) of O-phase HZO 630 may be more than 70%. In the M-phase HZO pillar 610, the content of M-phase HZO 640 may be more than 70%. In the T-phase HZO pillar 620, each of the content of O-phase HZO 630 and M-phase HZO 640 may be less than 70%. FIG. 10E depicts the different phases of HZO in the shape of pillars 610, 620, however interfaces between neighboring insertion pillars 610, 620 may not a regular straight line in some embodiments.

In some embodiments, interfaces between different phases of HZO may be observed by tunneling electron microscopy (TEM) and distribution (e.g., area ratio) of different phases of HZO may be analyzed by precession electron diffraction (PED). For example, different phases of the HZO may be detected roughly by TEM, then may be decoupled in detail by PED.

With reference to FIGS. 1A-10F, the integrated capacitors are described as MIM capacitors formed in RDL layers, BEOL interconnect layers or MEOL interconnect layers. In some embodiments, the integrated capacitors may be formed in other structures, such as in a ferroelectric FET (FeFET) or ferroelectric random access memory (FRAM) cell. For example, the insertion layer(s) may be positioned between a semiconductor fin and a gate structure of a FeFET or may be positioned above a drain epitaxial region of an FRAM between two metal layers.

Embodiments may provide advantages. Including the insertion layers 270, 272, the insertion pillars 610, 620 or both reduces or blocks trap generation in the T-phase HZO layers 209 and/or the T-phase insertion pillars 620, which greatly improves TDDB and MTTF of integrated capacitors while maintaining capacitance density.

In accordance with at least one embodiment, a device includes: a first electrode; a first interfacial layer in contact with the first electrode; a first insertion layer on the first interfacial layer, the first insertion layer having first orthorhombic-phase (O-phase) regions or first monoclinic-phase (M-phase) regions in a first area ratio that exceeds about 70%; a first dielectric layer on the first insertion layer, the first dielectric layer having tetragonal-phase (T-phase) regions in a second area ratio that exceeds those of second O-phase regions and second M-phase regions; a second insertion layer on the first dielectric layer, the second insertion layer having third O-phase regions or third M-phase regions in a third area ratio that exceeds about 70%; a second interfacial layer in contact with the second insertion layer, the second interfacial layer being a different material than the first interfacial layer; and a second electrode on the second interfacial layer.

In accordance with at least one embodiment, a device includes: a first electrode; a first interfacial layer in contact with the first electrode, the first interfacial layer above the first electrode in a first direction; a first insertion pillar on the first interfacial layer, the first insertion pillar having first orthorhombic-phase (O-phase) regions or first monoclinic-phase (M-phase) regions in a first area ratio that exceeds about 70%; a second insertion pillar adjacent the first insertion pillar in a second direction transverse the first direction, the second insertion pillar having tetragonal-phase (T-phase) regions in a second area ratio that exceeds those of second O-phase regions and second M-phase regions; a second interfacial layer on the first insertion pillar and the second insertion pillar, the second interfacial layer being a different material than the first interfacial layer; and a second electrode in contact with the second interfacial layer.

In accordance with at least one embodiment, a method includes: forming a first conductive electrode; forming a stack of nanoscale dielectric layers on the first conductive electrode, including: forming a first insertion layer having HfₓZr₁—XO₂, X being in a range of about 0.4 to about 1; and forming a second insertion layer having HfₛZr₁—ZO₂, Z being in a range of about 0.4 to about 1, the second insertion layer being formed on the first insertion layer; forming a second conductive electrode on the stack; and forming orthorhombic-phase (O-phase) regions, monoclinic-phase (M-phase) regions and tetragonal-phase (T-phase) regions in the first insertion layer and the second insertion layer by annealing the first conductive electrode, the stack and the second conductive electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first electrode;
a first interfacial layer in contact with the first electrode;
a first insertion layer on the first interfacial layer, the first insertion layer having first orthorhombic-phase (O-phase) regions or first monoclinic-phase (M-phase) regions in a first area ratio that exceeds about 70%;
a first dielectric layer on the first insertion layer, the first dielectric layer having tetragonal-phase (T-phase) regions in a second area ratio that exceeds those of second O-phase regions and second M-phase regions;
a second insertion layer on the first dielectric layer, the second insertion layer having third O-phase regions or third M-phase regions in a third area ratio that exceeds about 70%;
a second interfacial layer in contact with the second insertion layer; and
a second electrode on the second interfacial layer.

2. The device of claim 1, wherein the first insertion layer includes zirconium-doped hafnium oxide (HZO), the first dielectric layer includes HZO and the second insertion layer includes HZO.

3. The device of claim 1, wherein the first insertion layer includes silicon-doped hafnium oxide (HSO), the first dielectric layer includes HSO and the second insertion layer includes HSO.

4. The device of claim 1, wherein each of the first insertion layer, the second insertion layer and the first dielectric layer has thickness less than about 5 nanometers.

5. The device of claim 1, further comprising:
a second dielectric layer between the first dielectric layer and the second insertion layer, the second dielectric layer having second T-phase regions in a fourth area ratio that exceeds those of fourth O-phase regions and fourth M-phase regions; and
a third insertion layer between the first dielectric layer and the second dielectric layer, the third insertion layer having fifth O-phase regions or fifth M-phase regions in a fifth area ratio that exceeds about 70%.

6. The device of claim 5, wherein the third insertion layer is one of an O-phase or M-phase layer and the first and second insertion layers are the other of the O-phase or M-phase layer.

7. A device comprising:
a first electrode;
a first interfacial layer in contact with the first electrode, the first interfacial layer above the first electrode in a first direction;
a first insertion pillar on the first interfacial layer, the first insertion pillar having first orthorhombic-phase (O-phase) regions or first monoclinic-phase (M-phase) regions in a first area ratio that exceeds about 70%;
a second insertion pillar adjacent the first insertion pillar in a second direction transverse the first direction, the second insertion pillar having tetragonal-phase (T-phase) regions in a second area ratio that exceeds those of second O-phase regions and second M-phase regions;
a second interfacial layer on the first insertion pillar and the second insertion pillar; and
a second electrode in contact with the second interfacial layer.

8. The device of claim 7, further comprising:
a first insertion layer between the first and second insertion pillars and the first interfacial layer.

9. The device of claim 8, further comprising:
a second insertion layer between the first and second insertion pillars and the second interfacial layer.

10. The device of claim 9, further comprising:
a third insertion pillar on the first interfacial layer, the third insertion pillar having third orthorhombic-phase (O-phase) regions or third monoclinic-phase (M-phase) regions in a third area ratio that exceeds about 70%, the second insertion pillar being between the first insertion pillar and the third insertion pillar.

11. The device of claim 10, wherein the first insertion pillar is one of an O-phase or M-phase pillar and the third insertion pillar is the other of the O-phase or M-phase pillar.

12. The device of claim 7, wherein thicknesses of the first insertion pillar and the second insertion pillar in the first direction are in a range of about 4 nanometers to about 20 nanometers.

13. The device of claim 7, wherein an interface between sidewalls of the first insertion pillar and the second insertion pillar includes an area ratio of O-phase zirconium-doped hafnium oxide (HZO) that decreases in the second direction from the first insertion pillar toward the second insertion pillar.

14. A method, comprising:
forming a first conductive electrode;
forming a stack of nanoscale dielectric layers on the first conductive electrode, including:
forming a first insertion layer having Hf_{X}Zr_{1-X}O₂; and
forming a second insertion layer having Hf_{Z}Zr_{1-Z}O₂, the second insertion layer being formed on the first insertion layer;
forming a second conductive electrode on the stack; and
forming orthorhombic-phase (O-phase) regions, monoclinic-phase (M-phase) regions and tetragonal-phase (T-phase) regions in the first insertion layer and the second insertion layer by annealing the first conductive electrode, the stack and the second conductive electrode.

15. The method of claim 14, further comprising:
forming a first interfacial layer on the first conductive electrode prior to the forming a stack; and
forming a second interfacial layer on the stack prior to the forming a second conductive electrode.

16. The method of claim 14, wherein the first insertion layer is formed directly on the first conductive electrode and the second conductive electrode is formed directly on the second insertion layer.

17. The method of claim 14, further comprising:
forming a first dielectric layer having Hf_{Y}Zr_{1-Y}O₂, Y being less than about 0.3, the first dielectric layer being formed on the first insertion layer prior to the forming the second insertion layer.

18. The method of claim 14, wherein the forming orthorhombic-phase regions, monoclinic-phase regions and tetragonal-phase regions in the first insertion layer and the second insertion layer forms a first insertion pillar and a second insertion pillar adjacent the first insertion pillar, the second insertion pillar having a different area ratio of T-phase regions than the first insertion pillar.

19. The method of claim 14, wherein X is different than Z.

20. The method of claim 14, wherein
the forming a first insertion layer includes forming a first zirconium-doped hafnium oxide layer by atomic layer deposition to a thickness less than about 5 nanometers; and
the forming a second insertion layer includes forming a second zirconium-doped hafnium oxide layer by atomic layer deposition to a thickness less than about 5 nanometers.
